(19) United States
(12) Patent Application Publication
(10) Pub. No.: US 2003/0057988 A1
(43) Pub. Date: Mar. 27, 2003

(54) Semiconductor device inspecting method using conducting AFM

(75) Inventors: Hitoshi Maeda, Tokyo (JP); Fumihito Ohta, Tokyo (JP); Yukari Imai, Tokyo (JP); Toshikazu Tsutsui, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/160,006

(22) Filed: Jun. 4, 2002

(30) Foreign Application Priority Data
Sep. 25, 2001 (JP) 2001-291386

(51) Int. Cl. G01R 31/26

(52) U.S. Cl. 324/765

(57) ABSTRACT

A semiconductor device inspecting method is provided which can detect electric faults in an in-line inspection. The positive electrode of a variable DC power supply (2) is connected to the back or a peripheral portion of a semiconductor substrate (4) and the negative electrode of the variable DC power supply (2) is connected to a conductive cantilever (3). A scan is performed with a given forward bias voltage (e.g. 1.0 V) applied between the cantilever (3) and the semiconductor substrate (4) and with the cantilever (3) in contact with a target contact plug (9). The current flowing through the cantilever (3) is then monitored with an ammeter (1) to obtain a current characteristic of each contact plug, making it possible to detect conduction faults which cannot be detected by simply observing the configuration.

### BACKGROUND OF THE INVENTION

1. Field of the Invention

The present invention relates to a semiconductor device inspecting method and particularly to an inspection method which can be used in an in-line inspection.

2. Description of the Background Art

The recent dimensional reductions of semiconductor devices involve reductions in contact diameter, impurity layer junction depth, gate insulating film thickness, and so on, which are experiencing problems such as imperfect formation of contact openings, current leakages at PN junctions, and current leakages due to inferior formation of gate oxide films. Steady production of semiconductor devices requires that such faults be found at an early stage so that the measures can be fed back to the manufacturing process.

It is therefore important to detect faults to clear up the causes during an in-line inspection conducted in the course of the production line or during an off-line analysis of the completed products. However, existing in-line inspections cannot directly detect electric faults and therefore such electric faults must be detected during off-line analyses carried out after the process has ended. Finding faults thus takes time.

### SUMMARY OF THE INVENTION

It is an object of the present invention is to provide a semiconductor device inspecting method which can detect electric faults during an in-line inspection.

A first aspect of the present invention is directed to a method for inspecting a semiconductor device having semiconductor regions provided in a main surface of a semiconductor substrate and a plurality of contact plugs passing through an interlayer insulating film provided on the main surface of the semiconductor substrate to come in contact with the semiconductor regions. The semiconductor device inspecting method includes the steps (a) and (b), after placing the semiconductor device being under manufacture on an inspection stage of a conducting atomic force microscope, with one end of each of the plurality of contact plugs exposed in a surface of the interlayer insulating film. The step (a) is to apply a bias voltage between a cantilever of the conducting atomic force microscope and the semiconductor substrate, making a scan with the cantilever in contact with one contact plug selected from among the plurality of contact plugs, and detecting a current flowing through the cantilever. The step (b) is performed after applying the step (a) to the plurality of contact plugs. The step (b) is to compare the detected current values with a given threshold to determine an electric characteristic of the semiconductor device.

A semiconductor device being under manufacture is inspected with one end of each contact plug exposed in a surface of an interlayer insulating film, where a bias voltage is applied between the cantilever of a conducting atomic force microscope and the semiconductor substrate and the cantilever of the conducting atomic force microscope is brought into contact with the contact plug. Then the current is detected and an electric characteristic of the semiconductor device is inspected on the basis of the detected current. This method enables electric faults to be detected during an in-line inspection and realizes a simple and easy inspection by eliminating the need for arranging lines and electrodes for measurement, which conventional fault diagnosis techniques required.

Further, according to the present invention, the semiconductor device inspecting method further includes, prior to the step (a), a step of checking junction structures in the semiconductor substrate on the basis of layout information about the plurality of contact plugs and layout information about implantation masks for impurity implantation, and the step (a) comprises a step of setting the polarity and voltage value of the bias voltage on the basis of a result of the check and determining whether or not detecting the current with the cantilever under the set voltage conditions is useful, wherein, when useful, the current is detected under the set voltage conditions.

The junction structure in the semiconductor substrate is checked and the voltage conditions are set on the basis of the result of the check. Then a determination is made as to whether detecting the current under the set voltage conditions is useful. Accordingly, it is possible, for example, to avoid inspection of contact plugs connected to junction structures with which current cannot be measured for a structural reason, so as to enable an effective inspection.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram roughly showing a structure for measuring conduction characteristics of contacts with a conducting AFM;

FIG. 2 is a diagram showing the conduction characteristics of the contact plugs;

FIG. 3 is a diagram roughly showing a structure for measuring leakage characteristics of contacts with a conduction AFM;

FIG. 4 is a diagram showing the leakage characteristics of the contact plugs;

FIG. 5 is a diagram showing an example of junction structures contained in an actual semiconductor device;

FIG. 6 is a diagram showing a structure for realizing the semiconductor device inspecting method of the present invention;

FIGS. 7 and 8 show a flowchart illustrating the semiconductor device inspecting method of the present invention;

FIG. 9 is a diagram showing the appearance of a computer system for executing the semiconductor device inspecting method of the present invention; and

FIG. 10 is a diagram showing the structure of the computer system for executing the semiconductor device inspecting method of the present invention.

### DESCRIPTION OF THE PREFERRED EMBODIMENTS

The semiconductor device inspecting method of the present invention utilizes a conducting AFM. The conducting AFM is a kind of AFM (Atomic Force Microscope), which is a device capable of not only inspecting the configuration of a surface but also measuring electrical characteristics of a nanometer-level region by measuring a current flowing between a conductive cantilever and a sample, with the cantilever in contact with the sample. The use of the conducting AFM to inspect electric characteristics of semiconductor devices being manufactured enables detection of electric faults during an in-line inspection and realizes a simple and easy inspection by eliminating the need for lines and electrodes for measurement, which conventional fault diagnosis techniques required.

<A. Concept of Electric Characteristic Measurement>

<A-1. Measurement of Conduction Characteristics of Contacts (Conduction Test)>

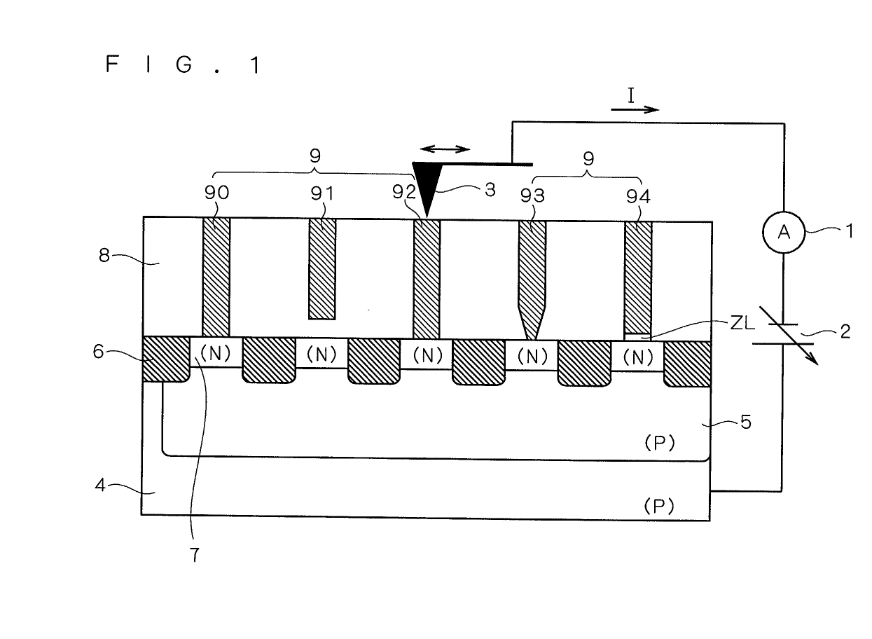

FIG. 1 roughly shows a structure for measuring conduction characteristics of contacts with a conducting AFM.

In FIG. 1, the P-type semiconductor substrate 4 has a P-type well region 5 formed in its main surface and element isolation insulating film 6 selectively formed in the surface of the P-type well region 5 to define a plurality of active regions. N-type impurity regions 7 are provided in the surfaces of the respective active regions, where the P-type well region 5 and the N-type impurity regions 7 form PN junctions.

The main surface of the semiconductor substrate 4 is covered by an interlayer insulating film 8 and a plurality of contact plugs 9 pass through the interlayer insulating film 8 to respectively reach the plurality of N-type impurity regions 7. Note that the plurality of contact plugs 9 include imperfectly formed plugs; the plurality of contact plugs 9 are shown at reference numbers so that they can be distinguished from each other.

That is to say, FIG. 1 shows contact plugs 90, 91, 92, 93 and 94 arranged in order from the left, where the contact plugs 90 and 92 are normal, the contact plug 91 is short of the N-type impurity region 7, the contact plug 93 has a tapered end and is hence in insufficient contact with the N-type impurity region 7, and the contact plug 94 is in insufficient contact with the N-type impurity region 7 due to the presence of an insulating film ZL at the substrate/contact interface.

When the contact plugs 90 to 94 are seen from above the interlayer insulating film 8, they all look normal in plan view, so that it is difficult to find the conduction faults by observing and inspecting their opening shape with a scanning electron microscope (SEM) etc.

Accordingly, in order to measure the conduction characteristics of the contact plugs 9, the semiconductor substrate 4 is placed on an inspection stage of the conducting AFM, the positive electrode of a variable DC power supply 2 is connected to the back or a peripheral portion of the semiconductor substrate 4 as shown in FIG. 1, and its negative electrode is connected to a conductive cantilever 3. Then, with a given forward bias voltage (e.g. 1.0 V) applied between the cantilever 3 and the semiconductor substrate 4, a scan is performed with the cantilever 3 in contact with a target contact plug 9.

The current flowing through the cantilever 3 is monitored with an ammeter 1 to obtain the current characteristic of each contact plug, which enables detection of conduction faults which cannot be detected by simply observing the configuration.

While effecting this inspection method requires that the diameter of the tip of the cantilever 3 be smaller than the diameter of the contact plugs 9, current semiconductor devices encounter no problem because the diameter of the contact plugs 9 is around 100 nm and the diameter of the tip of the cantilever 3 is several tens of nanometers or less.

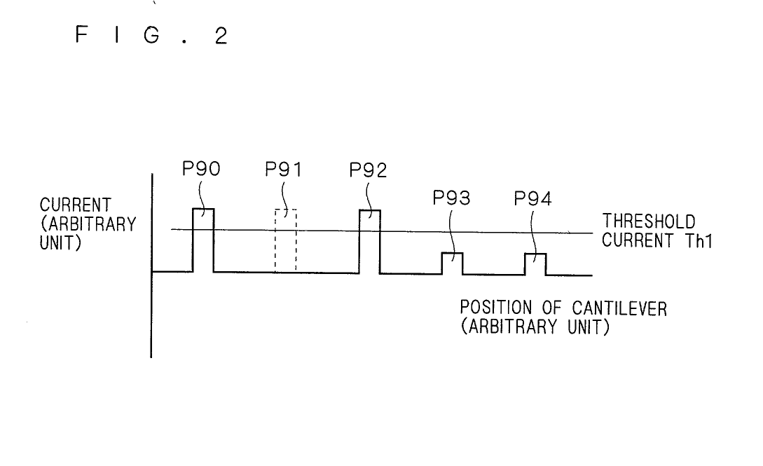

FIG. 2 shows the conduction characteristics of the contact plugs 9 measured by the method shown in FIG. 1. In FIG. 2, the horizontal axis shows the shift of position of the cantilever 3 (in an arbitrary unit) and the vertical axis shows the current value measured by the ammeter 1 (in an arbitrary unit).

While FIG. 2 shows pulse-like profiles P90 to P94, they respectively correspond to current profiles obtained when the cantilever 3 has been moved over the contact plugs 90 to 94. That is to say, the profiles P90 and P92 show the conduction profiles of the normal contact plugs 90 and 92; they show flows of a large current at the contacts between the cantilever 3 and the contact plugs 90 and 92 since a forward bias voltage is applied through the contact plugs 90 and 92 to the PN junctions formed by the P-type well region 5 and the N-type impurity regions 7.

The profile P91 shows the conduction characteristic of the contact plug 91 having an imperfectly formed opening and not reaching the N-type impurity region 7. Since the contact plug 91 does not reach the N-type impurity region 7, no current flows and no pulse-like profile is obtained. However, for convenience, an imaginary profile, which would be obtained if it had a normal opening, is shown with broken line as the profile P91.

The profiles P93 and P94 show the conduction characteristics of the contact plugs 93 and 94 which are in insufficient contact with the N-type impurity regions 7. Since a forward bias voltage, though not sufficient, is applied through the contact plugs 93 and 94 to the PN junctions formed by the P-type well region 5 and the N-type impurity regions 7, a current flows at the contacts between the cantilever 3 and the contact plugs 93 and 94. However, because the bias voltage is insufficient, the current value is smaller than that of the profiles P90 and P92.

As for the judgement of the conduction characteristics of the contact plugs 90 to 94, a determination can be made according to whether or not the profile current exceeds a given threshold current value. That is to say, as shown in FIG. 2, contact plugs having conduction faults can be distinguished by setting a threshold current value Th1 which is larger than the current obtained with the contact plug 91 having an imperfect opening and also than that obtained with the contact plugs 93 and 94 in insufficient contact with the N-type impurity regions 7.

<A-2. Measurement of Leakage Characteristics of PN Junctions (Leakage Test)>

Electric characteristics which can be measured with the conducting AFM include leakage characteristics of PN junctions, as well as the conduction characteristics shown above.

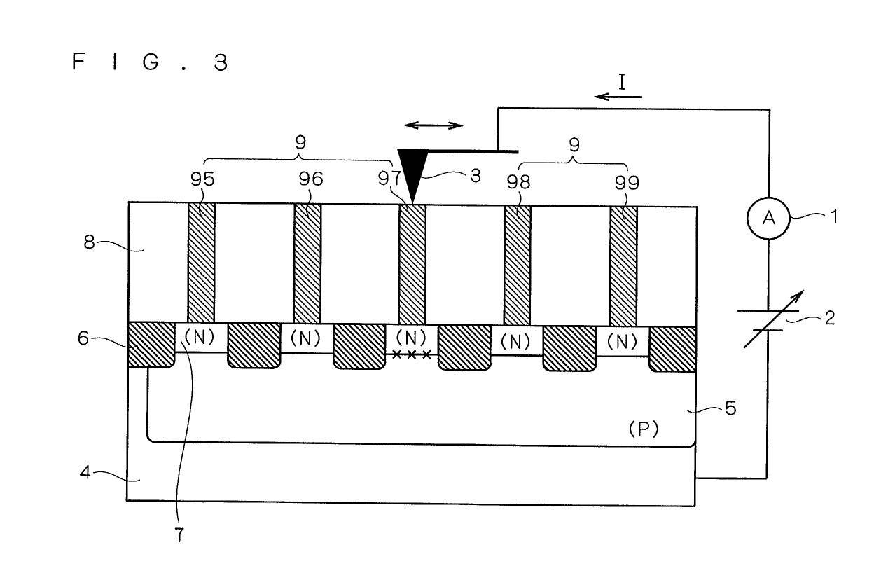

FIG. 3 roughly shows a structure for measuring the leakage characteristics of contacts with a conducting AFM. In FIG. 3, the same components as those shown in FIG. 1 are denoted by the same reference characters and not described again.

Note that the plurality of contact plugs 9 include one which is connected to an N-type impurity region 7 having a junction fault at the PN junction; the plurality of contact plugs 9 are shown at reference numbers so that they can be distinguished from each other.

That is to say, FIG. 3 shows contact plugs 95, 96, 97, 98 and 99 arranged in order from the left, where the contact plugs 95, 96, 98 and 99 are connected to N-type impurity regions 7 having normal PN junctions, and the contact plug 97 is connected to the N-type impurity region 7 having a junction fault at the PN junction.

When the contact plugs 95 to 99 are seen from above the interlayer insulating film 8, they all look normal in plan view, so that it is difficult to find the junction faults by observing and inspecting their opening shape with an SEM etc.

Accordingly, in order to measure the leakage characteristics of the contact plugs 9, the semiconductor substrate 4 is placed on an inspection stage of the conducting AFM, the negative electrode of the variable DC power supply 2 is connected to the back or a peripheral portion of the semiconductor substrate 4 as shown in FIG. 3, and the positive electrode of the variable DC power supply 2 is connected to the conductive cantilever 3. Then, with a given reverse bias voltage (e.g. 1.0 V) applied between the cantilever 3 and the semiconductor substrate 4, a scan is performed with the cantilever 3 in contact with a target contact plug 9.

The current flowing through the cantilever 3 is monitored with the ammeter 1 to obtain the leakage characteristics of the N-type impurity regions 7 to which the contact plugs are connected, which enables detection of leakage faults which cannot be detected by simply observing the configuration.

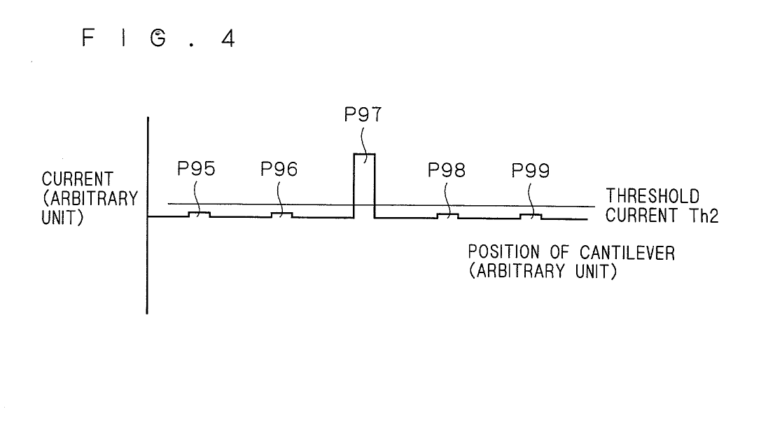

FIG. 4 shows the leakage characteristics of the contact plugs 9 measured by the method shown in FIG. 3. In FIG. 4, the horizontal axis shows the shift of position of the cantilever 3 (in an arbitrary unit) and the vertical axis shows the current value measured by the ammeter 1 (in an arbitrary unit).

While FIG. 4 shows pulse-like profiles P95 to P99, they respectively correspond to current profiles obtained when the cantilever 3 has been moved over the contact plugs 95 to 99. That is to say, the profiles P95, P96, P98 and P99 show the leakage current profiles obtained by scanning the contact plugs 95, 96, 98 and 99 connected to N-type impurity regions 7 having normal PN junctions, where current hardly flows when a reverse bias voltage is applied to the normal PN junctions formed by the P-type well region 5 and the N-type impurity regions 7, so that the current value of the profiles P95, P96, P98 and P99 is close to zero as shown in the diagram. While, in practice, current may not flow to such an extent as to form a pulse-like profile, FIG. 4 shows the pulse-like profiles for the sake of convenience.

On the other hand, the profile P97 shows the leakage current profile obtained by scanning the contact plug 97 connected to the N-type impurity region 7 having a junction fault at the PN junction. The profile shows that a large leakage current, which would not flow when the junction was normal, flows when a reverse bias voltage is applied to the PN junction having a junction fault.

As for the judgement of the leakage characteristics of the contact plugs 95 to 99, a determination can be made according to whether or not the profile current exceeds a given threshold current value. That is to say, as shown in FIG. 4, contact plugs connected to N-type impurity regions 7 having junction faults at PN junctions can be distinguished by setting a threshold current value Th2 which is larger than the leakage current obtained with the contact plugs 95, 96, 98 and 99 connected to the N-type impurity regions 7 having normal PN junctions.

<B. Actual Measurement of the Electric Characteristics>

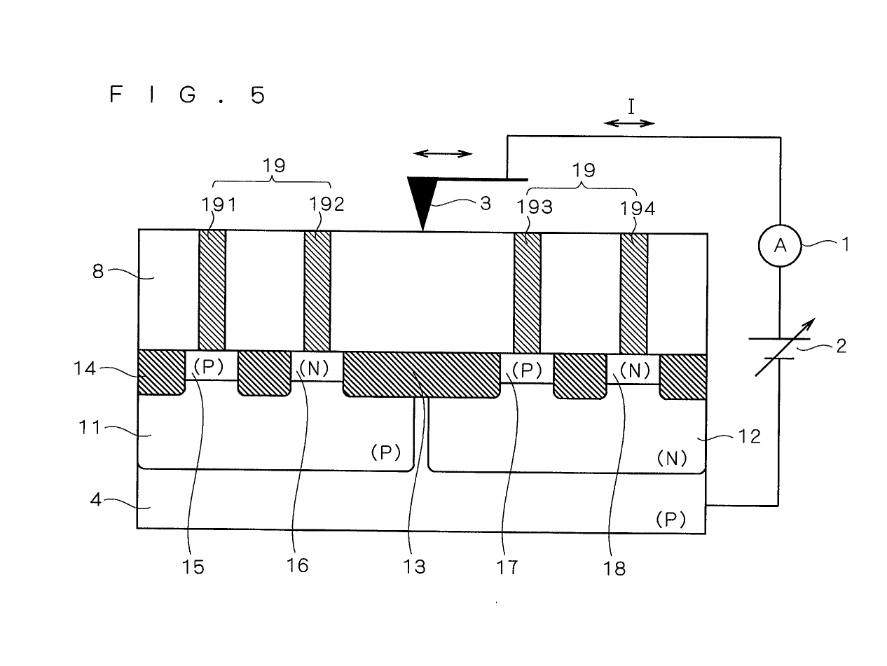

An actual semiconductor device has a plurality of contact plugs and a plurality of kinds of junction structures (which are formed of combinations of PN junctions, such as PN structure, PNP structure, NPN structure, etc.). It is therefore desirable to select which contact plugs are to be measured for which electric characteristic shown above (conduction characteristic or leakage characteristic). A structure and an operation flow for applying the inspection method of the invention to an inspection of an actual semiconductor device are now described referring to FIGS. 5 to 8. In FIG. 5, the same components as those shown in FIG. 1 are denoted by the same reference characters and are not described again.

First, FIG. 5 schematically shows an example of a junction structure contained in an actual semiconductor device.

In FIG. 5, the P-type semiconductor substrate 4 has a P-type well region 11 and an N-type well region 12 provided side by side in its main surface and an element isolation insulating film 13 provided between the P-type well region 11 and the N-type well region 12. Also, element isolation insulating film 14 is selectively provided in the surfaces of the P-type well region 11 and the N-type well region 12 to define a plurality of active regions. A P-type impurity region 15 and an N-type impurity region 16 are provided as source/drain regions in the surfaces of the active regions in the P-type well region 11 and a P-type impurity region 17 and an N-type impurity region 18 are provided as source/drain regions in the surfaces of the active regions in the N-type well region 12.

The main surface of the semiconductor substrate 4 is covered by an interlayer insulating film 8 and a plurality of contact plugs 19 pass through the interlayer insulating film 8 to reach the respective impurity regions.

Among the plurality of contact plugs 19, the plug reaching the P-type impurity region 15 is taken as a contact plug 191, the plug reaching the N-type impurity region 16 as a contact plug 192, the plug reaching the P-type impurity region 17 as a contact plug 193, and the plug reaching the N-type impurity region 18 as a contact plug 194.

While FIG. 5 shows a structure in which the negative electrode of the variable DC power supply 2 is connected to the back or a peripheral portion of the semiconductor substrate 4 and its positive electrode is connected to the conductive cantilever 3, it is assumed that the polarity of the variable DC power supply 2 can be arbitrarily changed and that the ammeter has a measurement range capable of measuring both the negative and positive currents.

<B-1. Structure of Apparatus>

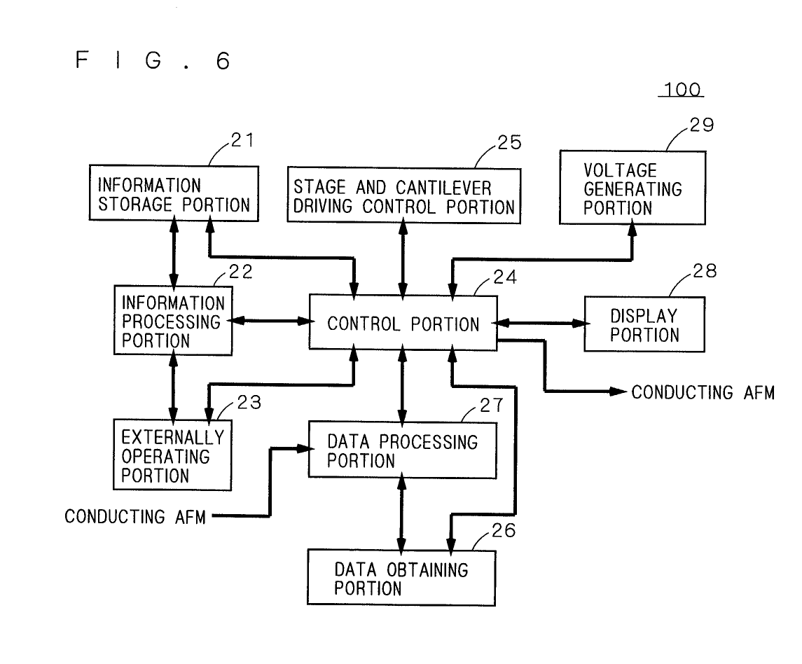

Next, the structure of an inspection apparatus 100 for measuring the electric characteristics of the contact plugs is described referring to the block diagram of FIG. 6.

As shown in FIG. 6, the inspection apparatus 100 comprises an information storage portion 21 for storing information such as the layout information about the contact plugs, an information processing portion 22, an externally operating portion 23 for externally operating the inspection apparatus 100, a control portion 24 for controlling operation of the entire inspection apparatus 100, a stage and cantilever driving control portion 25 for driving the inspection stage and the cantilever of the conducting AFM, a data obtaining portion 26 for obtaining measurement data about the current flow through the cantilever, a data processing portion 27 for processing data such as the measurement data obtained in the data obtaining portion 26, a display portion 28 for displaying inspection results etc., and a voltage generating portion 29 for generating the bias voltage.

<B-2. Operation of the Apparatus>

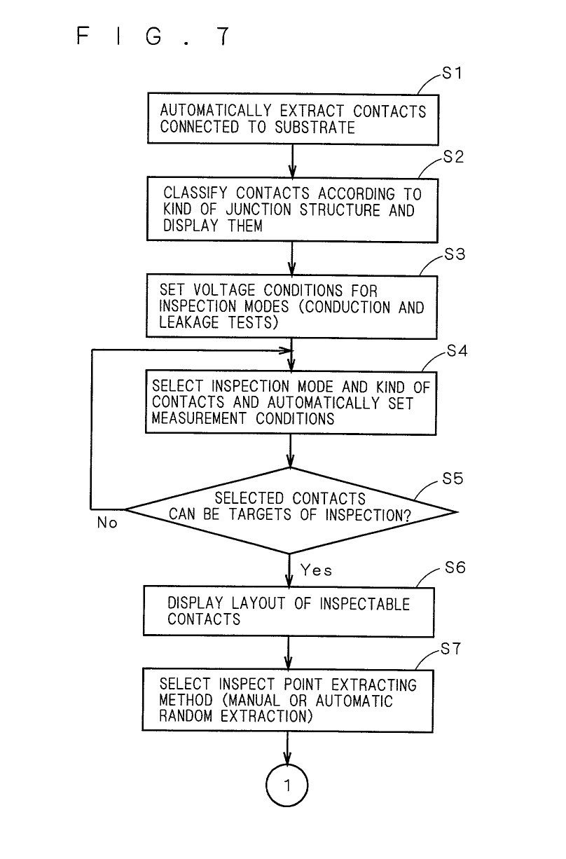

Now the procedure for inspecting the semiconductor device is described referring to the flowchart of FIGS. 7 and 8 showing the operation of the inspection apparatus 100, and the functions and operations of the individual components are also described referring to FIG. 6. In FIGS. 7 and 8, the reference character “1” shows that the two charts are connected at this point.

First, a target of the inspection, a semiconductor substrate being manufactured, is placed on the inspection stage of the conducting AFM. Then, in Step S1 shown in FIG. 7, the information processing portion 22 automatically extracts contact plugs connected to the semiconductor substrate on the basis of the layout information about the contact plugs and interconnections in individual layers which are stored in the information storage portion 21. The extracted information is displayed on the display portion 28.

Next, in Step S2 shown in FIG. 7, on the basis of substrate impurity information and implant mask layout information stored in the information storage portion 21, the information processing portion 22 checks the junction structure in the semiconductor substrate 4 and classifies the contact plugs extracted in Step S1 according to kind of junctions. The classified contact plugs are displayed in the display portion 28.

Now, in the example of the junction structure shown in FIG. 5, the display portion 28 displays classified different kinds of contact plugs, e.g. in different colors, as follows: the contact plug 191 connected to the P-type impurity region 15 formed in the surface of the P-type well region 11 (the plug 191 is connected to no junction structure), the contact plug 192 connected to the N-type impurity region 16 formed in the surface of the P-type well region 11 (the plug 192 is connected to a PN junction structure), the contact plug 193 connected to the P-type impurity region 17 formed in the surface of the N-type well region 12 (the plug 193 is connected to a PNP junction structure), and the contact plug 194 connected to the N-type impurity region 18 formed in the surface of the N-type well region 12 (the plug 194 is connected to a PN junction structure).

For the sake of simplicity, FIG. 5 shows the contact plugs 19 connected to a single layer, but the classification is made in the same way also with a multi-layer interconnection structure in which contact plugs are connected to the semiconductor substrate through a plurality of contacts formed in a plurality of layers.

Next, the control portion 24 generates files in which bias voltage conditions are set for each inspection mode (conduction test and leakage test: Step S3). The voltage conditions are shown below about the example of the contact plugs 191 to 194 classified in Step S2.

Common condition: the cantilever connected to a ground potential.

Inspection mode: Conduction test

Contact plug 191: +0.5 V applied to the semiconductor substrate 4.

Contact plug 192: +0.5 V applied to the semiconductor substrate 4.

Contact plug 193: connected to a PNP junction structure and no current flows; measurement useless.

Contact plug 194: +0.5 V applied to the semiconductor substrate 4.

Inspection mode: Leakage test

Contact plug 191: connected to no junction structure; measurement useless.

Contact plug 192: −1.0 V applied to the semiconductor substrate 4.

Contact plug 193: +1.0 V applied to the semiconductor substrate 4.

Contact plug 194: −1.0 V applied to the semiconductor substrate 4.

Next, monitoring the display portion 28, the operator operates the externally operating portion 23 to select an inspection mode and a kind of contact plugs to be inspected (contact plugs 191 to 194), and then the control portion 24 automatically extracts the corresponding file from the voltage condition files generated in Step S3 and controls the voltage generating portion 29 to automatically set the measurement conditions (Step S4).

Next, on the basis of the selected inspection mode and the selected kind of contact plugs, the control portion 24 determines whether the selected contact plugs can be targets of the inspection. That is to say, in an open inspection, for example, it is determined that the measurement of the contact plug 193 is useless as stated above, so it cannot be a target of the inspection. It is no use inspecting a contact plug which cannot be an inspection target. Accordingly, when the selected contact plugs cannot be inspection targets, the operator is informed of it through the display portion 28 and prompted to conduct Step S4 again to select other contact plugs. The flow moves to the next step when the selected contact plugs can be targets of the inspection (Step S5).

While an example in which a single kind of contact plugs are selected and inspected is describe below, a plurality of kinds of contact plugs can be inspected by repeating Step S6 and subsequent steps.

Step S6 displays contact plugs which can be inspection targets from among the contact plugs classified and displayed in the display portion 28 in Step S2.

Next, a selection is made as to how to extract inspection points from the inspectable contact plugs displayed in the display portion 28 (Step S7). That is to say, since a semiconductor device has a plurality of contact plugs of the same kind, all contact plugs are not inspected but samples are extracted and inspected. Step S7 thus determines the method of extraction.

The extraction methods include the two examples: in a first method, the operator manually extracts ones from among the inspectable contact plugs displayed in the display portion 28, and in a second method, the control portion 24 automatically extracts ones at random from among the inspectable contact plugs. In this case, the operator is required only to set the number of samples and the samples can be extracted in a well-balanced manner. That is to say, Step S7 selects the manual extraction or the automatic random extraction.

Next, in Step S8 shown in FIG. 8, the layout coordinates of an inspection point contact plug extracted in Step S7 is linked to the stage coordinates of the inspection stage, and the stage is automatically moved so that the inspection point reaches the position of the cantilever. The cantilever can thus be easily positioned above the inspection point.

Next, the conducting AFM operates as AFM and the cantilever performs a scan to acquire an AFM image (Step S9). To achieve this operation, the control portion 24 of the inspection apparatus 100 operates the conducting AFM in cooperation with the control system of the conducting AFM, using functions of the conducting AFM. The data about the AFM image is given from the conducting AFM to the data processing portion 27 of the inspection apparatus 100.

Next, the data processing portion 27 recognizes the obtained AFM image and compares it with the layout information about the contact plugs stored in the information storage portion 21 and automatically corrects positional incorrectness caused by an error in moving the inspection stage. This enables precise scan of the measured point (Step S10).

Next, the cantilever is brought into contact with the contact plug at the inspection point and made to scan on the basis of control from the stage and cantilever driving control portion 25, and the data obtaining portion 26 obtains the value of the current flowing through the cantilever (Step S11).

Then the control portion 24 checks whether all inspection point contact plugs extracted in Step S7 have been measured (Step S12); when all have been measured, the flow moves to the next step, and when an inspection point or points are left uninspected, Step S8 and subsequent steps are repeated.

Next, the data processing portion 27 processes the current values obtained at individual inspection points and generates a histogram of current values or calculates a mean value, maximum value, minimum value, etc., which are displayed in the display portion 28 (Step S13). The dispersion of the current values at the inspection points, for example, can thus be grasped.

Then the data processing portion 27 can obtain the distribution of normal and abnormal current values at the individual inspection points from the current value histogram, for example, which can be utilized to estimate the causes of the faults. Also, the data is used as the basis for setting the threshold for judging conduction faults or PN junction faults (Step S14).

An example of the threshold is shown below. In the conduction test, the threshold is set at 50 pA, for example, to determine that the conduction is good (OK) at 50 pA or above and no-good (NG) below 50 pA. In the leakage test, in the case of the contact plugs 192 and 194, the threshold is set at 10 pA, for example, to determine that the junction is good (OK) below 10 pA and no-good (NG) at 10 pA or above. In the case of the contact plug 193, the threshold is set at −10 pA, for example, to determine that the junction is good (OK) at over −10 pA (or when the absolute value is smaller than the absolute value 10 pA), and no-good (NG) at −10 pA or below (or when the absolute value is equal to or larger than the absolute value 10 pA).

Subsequently, on the basis of the results thus obtained, OK contact plugs and NG contact plugs are displayed on the display portion 28 in different colors (Step S15). The layout dependency etc. of the inferior contacts, e.g. the relation between the contact depth and the ill-conducting contact plugs, can thus be grasped.

Also on the basis of the obtained results, the display portion 28 displays the number and percentage of the NG contact plugs (Step S16). The frequency of occurrence of faults can thus be grasped.

Furthermore, from the AFM image recognized in Step S10, the diameters and areas of the individual inspection point contact plugs are measured (Step S17). The data processing portion 27 then processes the relation between the plug diameters and areas and the current values obtained at the individual inspection points, which is displayed as a correlation diagram on the display portion 28 (Step S18). The correlation between the contact plugs with conduction faults and the plan shapes of the contact plugs can thus be grasped.

While a plurality of same semiconductor devices are formed on a semiconductor substrate, the inspection cannot be applied to all of them; the inspection targets are limited. In semiconductor devices selected as inspection targets, the measurement can be conducted at the same inspection points as those determined in Step S7 shown above. However, needless to say, the inspection points can be varied device by device.

<C. Example of Realization of the Inspection Apparatus>

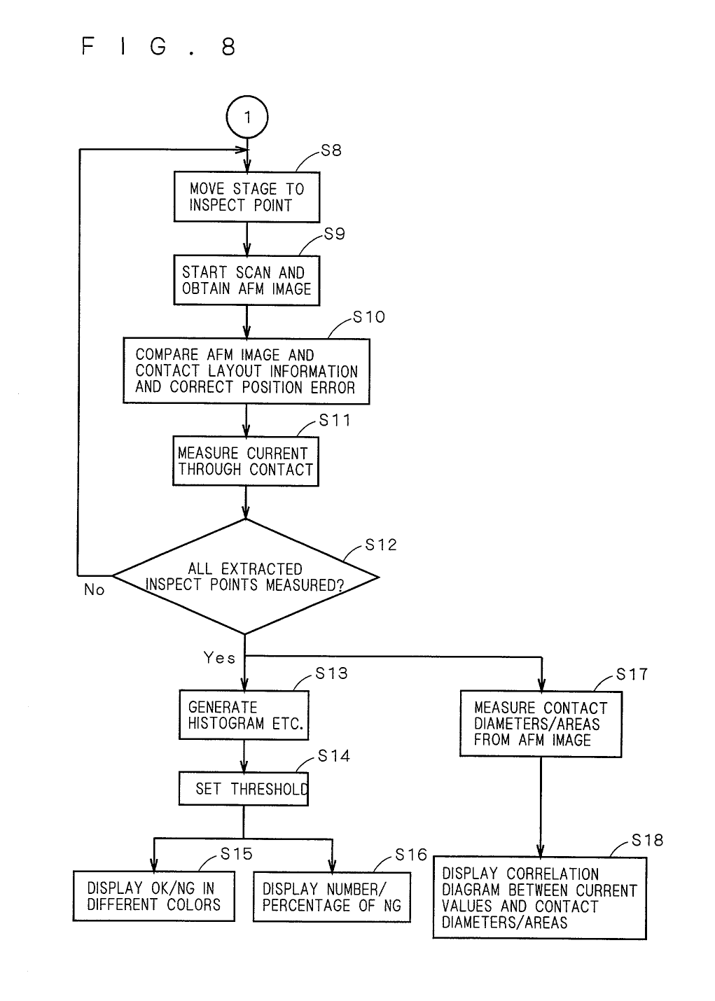

To implement the inspection apparatus 100 of the preferred embodiment described above, a computer system as shown in FIG. 9 can be used, for example.

That is to say, among the components of the inspection apparatus 100 shown in FIG. 6, the data obtaining portion 26 including the cantilever and the ammeter and the voltage generating portion 29 require dedicated instruments, but other components can be realized with the computer system shown in FIG. 9, which includes a computer body 101, a display device 102, a magnetic tape device 103 with a magnetic tape 104, a keyboard 105, a mouse 106, a CD-ROM device 107 with a CD-ROM (Compact Disk-Read Only Memory) 108, and a communication modem 109.

The functions of the information processing portion 22, control portion 24, stage and cantilever driving control portion 25 and data processing portion 27 can be realized by executing a computer program (an inspection method program) on the computer, in which case the program is supplied on a recording medium such as the magnetic tape 104, the CD-ROM 108, etc. This program can be transferred on a communication path in signal form, and can also be further downloaded on a recording medium.

The inspection method program is executed by the computer body 101 and the operator can perform the inspection by operating the keyboard 105 or the mouse 106 corresponding to the externally operating portion 23, while monitoring the display device 102 corresponding to the display portion 28.

The inspection method program may be supplied to the computer body 101 from another computer through the communication line and the communication modem 109.

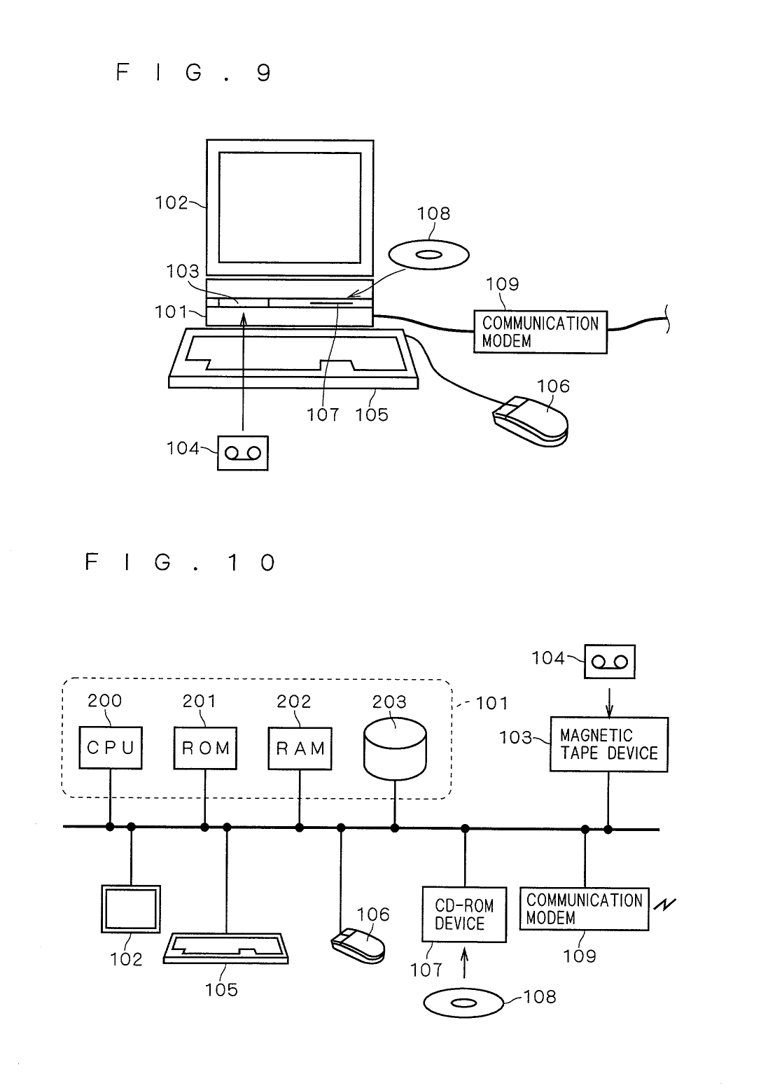

FIG. 10 is a block diagram showing the structure of the computer system shown in FIG. 9. The computer body 101 shown in FIG. 9 has a CPU (Central Processing Unit) 200, a ROM (Read Only Memory) 201, a RAM (Random Access Memory) 202, and a hard disk 203.

The CPU 200 operates while exchanging data with the display device 102, magnetic tape device 103, keyboard 105, mouse 106, CD-ROM device 107, communication modem 109, ROM 201, RAM 202, and hard disk 203.

The CPU 200 once stores the inspection method program recorded on the magnetic tape 104 or CD-ROM 108 into the hard disk 203. The CPU 200 then carries out the inspection by loading the inspection method program into the RAM 202 from the hard disk 203 as needed and executing the program.

The information storage portion 21 in the inspection apparatus 100 can be realized by using part of the RAM 202 other than the program storage region, or the information may be stored in the hard disk 203.

The computer system described above is just an example; the system is not limited to this system as long as it can execute the inspection method program. Also, the storage media are not limited to the magnetic tape 104 and the CD-ROM 108.

The computer system shown above is connected to a control system of the conducting AFM so as to operate the cantilever and the inspection stage, thus realizing the inspection apparatus 100. For the stage and cantilever driving control portion 25, a driving control system included in the conducting AFM may be used, in which case the control portion 24 is connected to this driving control system.

While the invention has been described in detail, the foregoing description is in all aspects illustrative and not restrictive. It is understood that numerous other modifications and variations can be devised without departing from the scope of the invention.

What is claimed is:

1. A method for inspecting a semiconductor device having semiconductor regions provided in a main surface of a semiconductor substrate and a plurality of contact plugs passing through an interlayer insulating film provided on said main surface of said semiconductor substrate to come in contact with said semiconductor regions, said semiconductor device inspecting method comprising the steps of:
after placing said semiconductor device being under manufacture on an inspection stage of a conducting atomic force microscope, with one end of each of said plurality of contact plugs exposed in a surface of said interlayer insulating film,
(a) applying a bias voltage between a cantilever of said conducting atomic force microscope and said semiconductor substrate, making a scan with said cantilever in contact with one contact plug selected from among said plurality of contact plugs, and detecting a current flowing through said cantilever; and
(b) after applying said step (a) to said plurality of contact plugs, comparing the detected current values with a given threshold to determine an electric characteristic of said semiconductor device.

2. The semiconductor device inspecting method according to claim 1,
wherein said step (a) comprises a step of, when said semiconductor regions form junction structures with another semiconductor region, applying said bias voltage in a forward direction with respect to said junction structures, and
said step (b) comprises a step of determining whether said plurality of contact plugs provide good conduction or have conduction faults, wherein a determination indicating good conduction is made when said detected current value is equal to or higher than said given threshold.

3. The semiconductor device inspecting method according to claim 1,
wherein said step (a) comprises a step of, when said semiconductor regions form junction structures with another semiconductor region, applying said bias voltage in a reverse direction with respect to said junction structures, and
said step (b) comprises a step of determining whether or not a PN junction in said semiconductor substrate suffers a current leakage, wherein a determination indicating no current leakage at said PN junction is made when said detected current value has an absolute value smaller than said given threshold.

4. The semiconductor device inspecting method according to claim 1, further comprising, prior to said step (a), a step of checking junction structures in said semiconductor substrate on the basis of layout information about said plurality of contact plugs and layout information about implantation masks for impurity implantation,
wherein said step (a) comprises a step of setting the polarity and voltage value of said bias voltage on the basis of a result of said check and determining whether or not detecting said current with said cantilever under said set voltage conditions is useful, wherein, when useful, said current is detected under said set voltage conditions.

5. The semiconductor device inspecting method according to claim 4, wherein said step (a) comprises a step of classifying said plurality of contact plugs on the basis of the result of said check, wherein plugs connected to a same kind of junction structures are classified as plugs of a same kind, and setting said voltage conditions on the basis of the classification.

6. The semiconductor device inspecting method according to claim 4, wherein said step (a) comprises a step of changing the polarity of said bias voltage on the basis of whether said plurality of contact plugs are inspected for conduction faults or for current leakages at PN junctions in said semiconductor substrate.

7. The semiconductor device inspecting method according to claim 4,
wherein said step (a) comprises the steps of,
prior to detecting said current flowing through said cantilever, moving said inspection stage on the basis of the layout information about said plurality of contact plugs to locate said selected contact plug under said cantilever,
obtaining an AFM image of the end of said selected contact plug by scanning with said cantilever of said conducting atomic force microscope, and
correcting a positional error of said cantilever on the basis of said AFM image.

8. The semiconductor device inspecting method according to claim 4, wherein said step (b) comprises a step of determining said given threshold on the basis of said current values detected from said plurality of contact plugs.

9. The semiconductor device inspecting method according to claim 4, wherein said step (b) comprises a step of generating a histogram on the basis of said current values detected from said plurality of contact plugs.
